(19) United States
(12) Patent Application Publication
(10) Pub. No.: US 2025/0054769 A1
(43) Pub. Date: Feb. 13, 2025

(54) METHOD FOR REDUCING VARIATIONS IN MASK TOPOGRAPHY

(71) Applicant: Lam Research Corporation, Fremont, CA (US)

(72) Inventors: Hsu-Cheng HUANG, Newark, CA (US); Sang Jun CHO, San Ramon, CA (US); Sriharsha JAYANTI, Fremont, CA (US); Gerardo DELGADINO, Milpitas, CA (US); Steven CHUANG, Fremont, CA (US)

(73) Assignee: Lam Research Corporation, Fremont, CA (US)

(21) Appl. No.: 18/724,531

(22) PCT Filed: Dec. 5, 2022
(86) PCT No.: PCT/US2022/080953

§ 371 Date: Jun. 26, 2024

Related U.S. Application Data
(60) Provisional application No. 63/267,044, filed on Jan. 21, 2022.

(51) Int. Cl. H01L 21/3105; H01L 21/311

(52) U.S. Cl. CPC H01L 21/31055; H01L 21/31144

(57) ABSTRACT

A patterning method includes etching a mask formed above a stack of two or more layers where the mask comprises a first patterned structure, a second patterned structure above the first patterned structure, where portions of the second patterned structure intersect the first patterned structure to form intersections and at least an opening. The mask includes a structure vertically between portions of the second patterned structure and the stack. The method includes etching a first layer of the stack through the opening and exposing a top surface of a second layer below the first layer, etching and removing the first patterned structure and the second patterned structure selectively to the first layer and the top surface of the second layer to form a planar mask comprising the first layer. The method further includes etching the second layer of the stack using the planar mask.

### CLAIM FOR PRIORITY

This application is a continuation of and claims the benefit of priority to U.S. Provisional Patent Application No. 63/267,044, filed on Jan. 21, 2022, titled “METHOD FOR REDUCING VARIATIONS IN MASK TOPOGRAPHY,” and which is incorporated by reference in its entirety.

### BACKGROUND

Alternate patterning techniques to Extreme Ultraviolet (EUV) lithography are highly useful for improving throughput and reducing cost. However, to obtain feature sizes that are comparable to those obtained by EUV, dual and quadruple patterning techniques may be utilized to form preliminary masks. Creation of holes or vias necessitate the use of at least two layers where features in each layer intersect to produce a preliminary non-planar mask with hole features. However, pattern transfer into a layer directly below through such preliminary non-planar masks can cause non-uniformity in feature sizes as well as in depth of holes produced in layers below. Non-uniformity may arise from non-uniform pattern transfer into the layer directly below the preliminary mask. As such, it is useful to find ways to reduce variation during pattern transfer to improve uniformity in patterned features.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1A is an isometric illustration of a non-planar mask structure above a patterning layer, in accordance with at least one embodiment.

FIG. 1B is plan-view illustration of the structure in FIG. 1A, in accordance with at least one embodiment.

FIG. 2A is an isometric illustration of a portion of the structure in FIG. 1A, prior to removal of a patterning layer, in accordance with at least one embodiment.

FIG. 2B is a cross-sectional illustration of the structure through a line A-A′ in FIG. 2A, in accordance with at least one embodiment.

FIG. 2C is a cross-sectional illustration of the structure in FIG. 2A through the line B-B′, in accordance with at least one embodiment.

FIG. 3A is a cross-sectional illustration of the structure in FIG. 2A following the process to etch a planarization layer, in accordance with at least one embodiment.

FIG. 3B is an isometric illustration of the structure in FIG. 3A following the process to etch a layer below a hardmask, in accordance with at least one embodiment.

FIG. 3C is an isometric illustration of the structure in FIG. 3B following a process to selectively etch lines in the hardmask from above the layer, in accordance with at least one embodiment.

FIG. 4A is an isometric illustration of the structure in FIG. 3C after etching lines in the hardmask and a portion of the planarization layer to form a planar mask, in accordance with at least one embodiment.

FIG. 4B is a cross-sectional illustration of variation in surface topography of the planar mask, in accordance with at least one embodiment.

FIG. 5A is an isometric illustration of the structure in FIG. 3B that further includes a stack below the hardmask, in accordance with at least one embodiment.

FIG. 5B is an isometric illustration of the structure in FIG. 5A following the process to etch hardmask selectively with respect to adjacent layers, in accordance with at least one embodiment.

FIG. 5C is an isometric illustration of the structure in FIG. 5B following the process to remove pillar portions of the hardmask resulting from non-planar hardmask topography, in accordance with at least one embodiment.

FIG. 6A is an isometric illustration of the structure in FIG. 5C following the process to etch a layer and form a planar mask, in accordance with an embodiment of the present disclosure.

FIG. 6B is a cross-sectional illustration of the structure in FIG. 6A through the line A-A′, in accordance with at least one embodiment.

FIG. 7A is a cross-sectional illustration of the structure in FIG. 5B following the process to remove pillar portions, in accordance with at least one embodiment.

FIG. 7B is a cross-sectional illustration of the structure in FIG. 7A following the process to planarize the structure, in accordance with at least one embodiment.

FIG. 7C is a plot of the flow of halogens during etching of hardmask in FIG. 5A.

FIG. 8A is an isometric illustration of the structure in FIG. 5A where the stack includes a dielectric above a substrate, in accordance with at least one embodiment.

FIG. 8B is an isometric illustration of the structure in FIG. 8A following the process to etch hardmask, in accordance with an embodiment of the present disclosure.

FIG. 8C is an isometric illustration of the structure in FIG. 8B following the process to etch a layer and form a planar mask, in accordance with at least one embodiment.

FIG. 9A is an isometric illustration of the structure in FIG. 8C following the process to etch a dielectric using the planar mask, in accordance with at least one embodiment.

FIG. 9B is a cross-sectional illustration of the structure in FIG. 9A though the line A-A′, in accordance with at least one embodiment.

FIG. 10 is a plan-view illustration of a larger mesh structure 1000 of which the structure in FIG. 9A is a part of, in accordance with at least one embodiment.

FIG. 11A is an isometric illustration of a mask, where a first patterned structure and a second patterned structure intersect at an angle, theta that is different from 90 degrees.

FIG. 11B a cross-sectional illustration of the structure in FIG. 11A through the line A-A′, in accordance with at least one embodiment.

FIG. 12 illustrates a computer system communicatively coupled with a display, in accordance with at least one embodiment.

### DETAILED DESCRIPTION

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

A method for reducing variation in mask topography is described, in accordance with at least one embodiment. In the following description, numerous specific details are set forth, such as structural schemes, to provide a thorough understanding of embodiments of the present disclosure. It will be apparent to one skilled in the art that embodiments of the present disclosure may be practiced without these specific details. In other instances, well-known features, such as etch equipment operations, are described in lesser detail to not unnecessarily obscure embodiments of the present disclosure. Furthermore, it is to be understood that the various embodiments shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an embodiment” or “one embodiment” or “some embodiments” means that a particular feature, structure, function, or characteristic described in connection with the embodiment is included in at least one embodiment of the disclosure. Thus, the appearances of the phrase “in an embodiment” or “in one embodiment” or “some embodiments” in various places throughout this specification are not necessarily referring to the same embodiment of the disclosure. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that the two or more elements co-operate or interact with each other (e.g., as in a cause an effect relationship).

The terms “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

The term “adjacent” here generally refers to a position of a thing being next to (e.g., immediately next to or close to with one or more things between them) or adjoining another thing (e.g., abutting it).

Unless otherwise specified in the explicit context of their use, the terms “substantially equal,” “about equal” and “approximately equal” mean that there is no more than incidental variation between two things so described. In the art, such variation is typically no more than +/−10% of the referred value.

Patterning of feature sizes in semiconductor device fabrication are typically performed by lithographic techniques. Lithography at 193 nm and EUV wavelengths are typically utilized to pattern features on layers of a substrate. Of the two, EUV lithography may be utilized to pattern feature sizes down to 5 nm. However, through put constraint and costs can be an issue.

Alternative patterning techniques using double patterning and quadruple patterning methods have been implemented to reduce feature sizes in line structures. However, to produce holes or openings for vias requires patterns to be formed on two levels. For example, parallel lines can be patterned on two different layers. A first set of parallel lines can be formed on a first level and arranged orthogonally or at some angle with respect to a second set of parallel lines formed on a second level. The first level may be above or below the second level. Intersection between the first set of parallel line and the second set of parallel lines produces holes or openings. The arrangement of the two set of parallel lines produces a non-planar mask.

However, when transferring patterns through the. non-planar mask with intersecting patterned lines introduces significant variations. Issues such as differential rates of material erosion, ion charging effects, and variations in line structures can cause size and shape variations between holes patterned.

In at least one embodiment, a technique is described that reduces variations in both shape and size of holes patterned. In at least one embodiment, the technique includes producing a planar masking layer below the intersecting parallel lines, by transferring the pattern of the non-planar mask on to one or more planar masking layers below.

In at least one embodiment, planarizing includes etching a masking layer and then selectively etching and removing the intersecting lines above to produce a planar mask having a substantially flat upper surface. In at least one embodiment, the planar mask can then be utilized to pattern permanent features in dielectric layers, for example. In at least one embodiment, the planar mask may or may not include materials that can be selectively patterned with respect to the intersecting lines. In at least one embodiment, it is useful for the intersecting lines to be removed selectively to the planar mask.

In at least one embodiment, the masking layer can include a combination of layers including a relatively thin upper layer and a thicker lower masking layer below the upper masking layer. In at least one embodiment, the upper masking layer may act as a barrier during etching and removal of the intersecting lines and other materials in the non-planar mask that may be similar to those of the lower masking layer. In at least one embodiment, the non-planar mask is etched and removed after a planar mask comprising the upper masking layer is formed. In at least one embodiment, this planar mask can be utilized to pattern the thicker lower masking layer to form a secondary mask. In at least one embodiment, a secondary mask can be beneficial for patterning thicker stacks of one or more dielectric materials, for example. In at least one embodiment, the variation in height in the secondary mask is significantly reduced and openings in the mask have substantial spatial uniformity compared to a process where the non-planar mask is not removed or one where the non-planar mask is alone used to pattern openings.

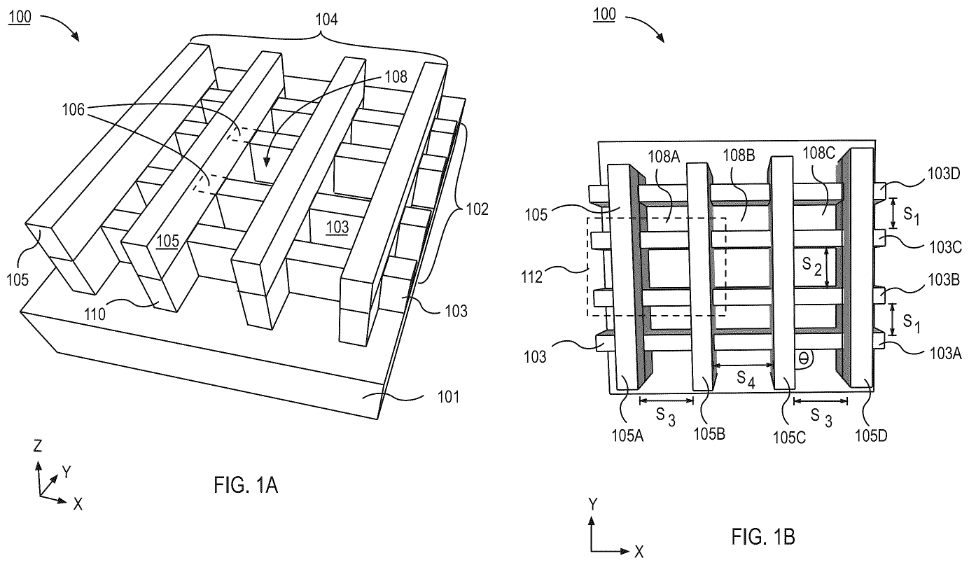

FIG. 1A is a cross sectional illustration of mask 100 formed above stack 101. Mask 100 includes first patterned structure or patterned structure 102 including at least a first material, in at least one embodiment. In at least one embodiment, second patterned structure or patterned structure 104 including at least a second material is above patterned structure 102. In at least one embodiment, portions of patterned structure 104 intersect patterned structure 104 to form intersections 106 and openings 108, where openings 108 expose an upper most layer of stack 101. In at least one embodiment, openings 108 can have a width in the range of 3 nm to 60 nm.

In at least one embodiment, patterned structures 102 and 104 can include a plurality of lines that are connected or separate and other structures. In at least one embodiment, patterned structure 102 includes plurality of lines such as lines 103. In at least one embodiment, lines 103 are substantially parallel to each other. In at least one embodiment, patterned structure 104 includes a plurality of lines, such as lines 105. In at least one embodiment, lines 105 are also substantially parallel to each other.

In at least one embodiment, mask 100 further includes structure 110 including a third material. In at least one embodiment, structure 110 is vertically between portions of patterned structure 102 and stack 101. In at least one embodiment, the third material is different from the first material or the second material to provide etch selectivity.

FIG. 1B is a plan-view illustration of mask 100. Lines 103 and 105 may generally intersect at a range of angles, in at least one embodiment. In at least one embodiment, for lines 103 and 105 that are parallel, the angle of intersection, theta, produces holes that are aligned along a general direction. In at least one embodiment, lines 103 intersect lines 105 at substantially 90 degrees. In at least one embodiment, openings 108A, 108B, 108C etc. are substantially vertically aligned.

In at least one embodiment, lines 103 may be spaced apart by a distance that is substantially uniform or can be spaced apart by varying extent. In at least one embodiment, a first pair of lines, such as lines 103A and 103B are spaced separated by a distance S₁, and a second pair of lines, such as lines 103C and 103D are also spaced apart by S₁. In at least one embodiment, first pair of lines 103A and 103B can be separated from the second pair of lines 103C and 103D by a distance S₂, as shown (distance between 103B and 103C, for example). In at least one embodiment, spacing S₁ and S₂ can be controlled by patterning feature sizes to a particular specification prior to forming lines 103.

In at least one embodiment, lines 105 may be spaced apart by a distance that is substantially uniform or can be spaced apart by varying extent. In at least one embodiment, a first pair of lines, such as lines 105A and 105B are spaced separated by distance S₁, and second pair of lines 105C and 105D are also spaced apart by S₃. In at least one embodiment, the first pair of lines 105A and 105B can be separated from the second pair of lines 105C and 105D by a distance S₄, as shown (distance between 105B and 105C, for example). In at least one embodiment, spacing S₃ and S₄ can be controlled by patterning feature sizes to a particular specification prior to forming lines 105.

In at least one embodiment, S₁, S₂, S₃ and S₄ can determine the size of openings 108A, 108B etc. In at least one embodiment, it may be useful for S₁, S₂, S₃ and S₄ to be substantially identical. In at least one embodiment, other factors such as widths of lines 103 and 105 also affects the uniformity of openings 108A, 108B etc.

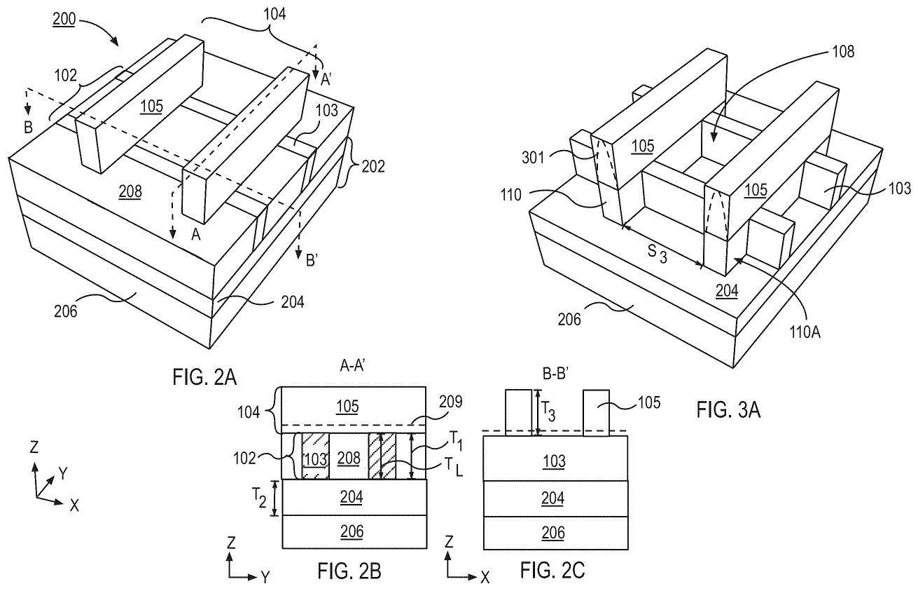

FIGS. 2A-4A are illustrations of various structures depicting various stages of a flow for producing a mask with reduced topography, in at least one embodiment.

FIG. 2A is an isometric illustration of a portion 112 of the mask 100 (herein structure 200) in FIG. 1B, in at least one embodiment. In at least one embodiment, structure 200 includes one or more features of the mask 100 such as lines 103 and 105. As shown, lines 103 are parallel and lines 105 are parallel. In at least one embodiment, lines 103 intersect lines 105 at an angle of approximately 90 degrees. In at least one embodiment, lines 103 and 105 are above stack 202. In at least one embodiment, stack 202 includes layer 204 above layer 206. Layer 208 fills a space between lines 103.

FIG. 2B is a cross-sectional illustration through a line A-A′ of the structure in FIG. 2A, in at least one embodiment. In at least one embodiment, depending on thickness T₁ of layer 208, lines 105 extends directly on layer 208 or partially on layer 208 and partially on lines 103. In at least one embodiment, thickness T₁, is substantially the same as thickness T₁ of the lines 103. In at least one embodiment, lines 105 is partially on layer 208 and partially on lines 103. In at least one embodiment, thickness T₁ is greater than thickness T_{L} as indicated by dashed lines 209.

In at least one embodiment, lines 103 and 105 include a silicon oxide, silicon oxynitride, silicon carbide, silicon nitride, polysilicon or amorphous silicon. In at least one embodiment, lines 103 and 105 can include a same material. In at least one embodiment, lines 103 and 105 can include a different material.

In at least one embodiment, layer 208 includes one or more carbon containing materials, such as an amorphous carbon. In at least one embodiment, materials such as amorphous carbon can be spun on layer 206 and on patterned structure 102. In at least one embodiment, line structure 104 can be fabricated on amorphous carbon. In one such embodiment, layer 204 can include silicon oxide, silicon oxynitride, silicon oxide doped with carbon, silicon nitride or carbon doped silicon nitride. In at least one embodiment, layer 204 has a thickness T₂, that can be less than, equal to or greater than thickness T₁. In at least one embodiment, removal of layer 208 in a downstream operation without etching layer 204 is highly useful to produce a mask composed of layer 204 with substantial planarity.

In at least one embodiment, layer 208 includes one or more carbon containing materials, such as an amorphous carbon. In one such embodiment, layer 204 can also include carbon containing materials, such as an amorphous carbon. In at least one embodiment, layer 204 has a thickness T₂, that can be substantially greater than thickness T₁. In at least one embodiment, thickness T₂>thickness T₁ facilitates removal of layer 208 in a downstream operation without etching all of the layer 204. In at least one embodiment, layer 204 can then be utilized to etch layer 206 in a downstream operation.

FIG. 2C is a cross-sectional illustration through a line B-B′ of the structure in FIG. 2A, in at least one embodiment. In at least one embodiment, lines 105 are in contact with a portion of the lines 103. In at least one embodiment, lines 105 have a thickness T₃. In at least one embodiment, thickness T₃ may be greater than, less than or substantially equal to thickness T₁.

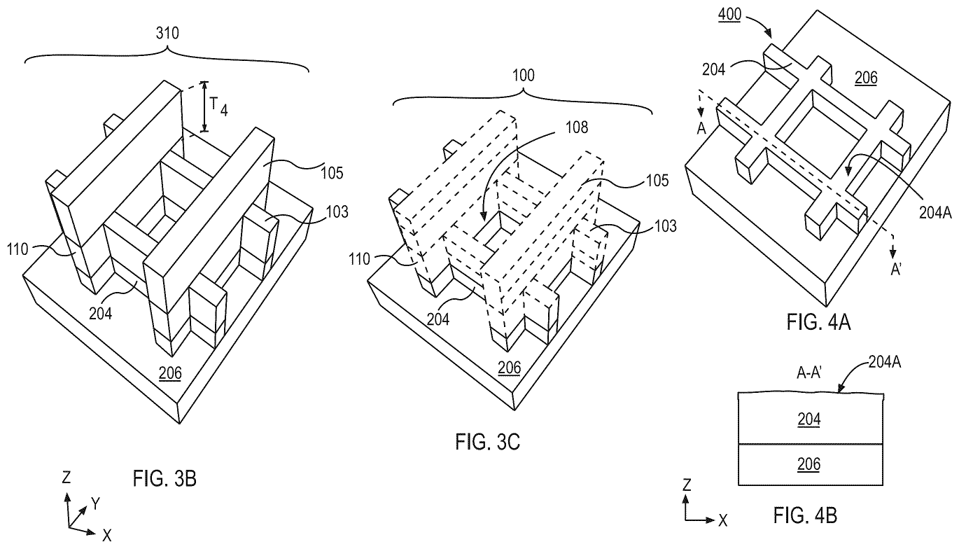

FIG. 3A is a cross-sectional illustration of the structure 200 in FIG. 2A following a process to etch the layer 208 and form structure 110, in at least one embodiment. In at least one embodiment, a plasma etch process including O₂ may be utilized to etch layer 208 selectively with respect to layer 204 and lines 103 and 105. In at least one embodiment, the plasma etch process forms structure 110 having substantially vertical sidewalls 110A. In at least one embodiment, spacing S₃, between spacing between structure 110 under each line 105, is substantially the same as the spacing between lines 105 because of substantially vertical sidewalls 110A. In at least one embodiment, lines 105 may be rounded, as indicated by dashed lines 301, prior to etching layer 208 to provide etch uniformity between different openings 108.

In at least one embodiment, where material of structure 110 includes a material that is substantially similar to layer 204 etching to form structure 110 can also recess layer 204.

FIG. 3B is an isometric illustration of the structure in FIG. 3A following the process to etch layer 204 to form mask 310, in at least one embodiment. In at least one embodiment, layer 204 includes a material that can be etched selectively with respect to the materials of lines 103 and 105, and layer 206.

In at least one embodiment, layer 204 includes a material such as silicon and one or more of oxygen or nitrogen, or polysilicon (a material different from a material of structure 110). In at least one embodiment, where lines 103 and 105 include a single material, then layer 204 includes a material that is different from a respective material of lines 103 and 105.

In at least one embodiment, upper portions of lines 103 and 105 may be etched during etching of layer 204. In at least one embodiment, uppermost surface of layer 204 is not exposed. In at least one embodiment, plasma etch process may be selective to the material of structure 110 during the etch process, even though structure 110 is designed to be removed at a later operation.

In at least one embodiment, the material of structure 110 includes one or more carbon containing materials, such as an amorphous carbon and layer 204 includes one or more carbon containing materials, such as an amorphous carbon.

In at least one embodiment, the material of structure 110 includes silicon and one or more of nitrogen, oxygen or carbon. In at least one embodiment, such materials can have a lower theoretical material density than a density of material of lines 103 and 105.

In at least one embodiment, the process to etch layer 204 to form mask 310 is performed by a third party. In at least one embodiment, layer 204 is patterned and has an outline of lines 103 and lines 105. In at least one embodiment, process to remove lines 105 and lines 103 to form mask 100 is described below in association with FIG. 3C.

FIG. 3C is an isometric illustration of the structure in FIG. 3B following a process to selectively etch lines 103 and 105 from above layer 204, in at least one embodiment.

In at least one embodiment, non-planar mask 100 is removed including lines 103 and 105 (within dashed lines) from the above layer 204, that is patterned, prior to continuing to etch layer 206 below. In at least one embodiment, removal of lines 103 and 105 provide patterning benefits. Problems such as uneven ion scattering from lines 103 and 105 during the etch process can lead to deformation in a shape of opening 108 when layer 206 is subsequently etched. Furthermore, uneven polymer deposition on lines 103 compared to lines 105 can lead to reduced selectivity between layer 206 and mask 100. Uneven etch selectivity can lead to degradation at least 50% of the periphery of opening 108.

In at least one embodiment, layer 206 includes a material such as silicon and one or more of oxygen or nitrogen, or silicon and carbon and one or more of oxygen or nitrogen. In at least one embodiment, these materials may be substantially like materials of mask 100 causing degradation of mask prior to completion of etch of layer 206.

In at least one embodiment, plasma etch process removes non-planar mask 100 (within dashed lines) with minimal consumption of layer 204. In at least one embodiment, etch chemistry is dependent on the material of lines 103 and 105 and can include halogen containing gases: CHₓ⁻, Br⁻, Clx⁻, or I⁻. In at least one embodiment, gas flow can range between 0.5 sccm to 500 sccm. In addition, other gases such as CF₄, CH₂F₂, C₄F₈, C₄F₆, Ar, and/or O₂ may also be utilized. In at least one embodiment, structure 110 is also removed during the etch process. Removal of lines 103 and 105 and structure 110 will be discussed in further detail below.

FIG. 4A is an isometric illustration of the structure in FIG. 3C after etching lines 103 and 105 and structure 110, in at least one embodiment. In at least one embodiment, patterned layer 204 forms mask 400. In at least one embodiment, the process described above begins with non-planar mask 100 and forms a mask 400 that is substantially planar but can have variations in topography of uppermost surface 204A.

In at least one embodiment, the variation in topography of uppermost surface 204A is shown in the cross-sectional illustration of FIG. 4B. In at least one embodiment, the variation in thickness of uppermost surface 204A is less than 50% of the original thickness T₄, of lines 105 (FIG. 3B). In at least one embodiment, uppermost surface 204A that is uneven is not substantial to prevent opening 108 (dashed lines) to be extended into layer 206 with fidelity.

In at least one embodiment, layer 206 includes carbon or dielectric

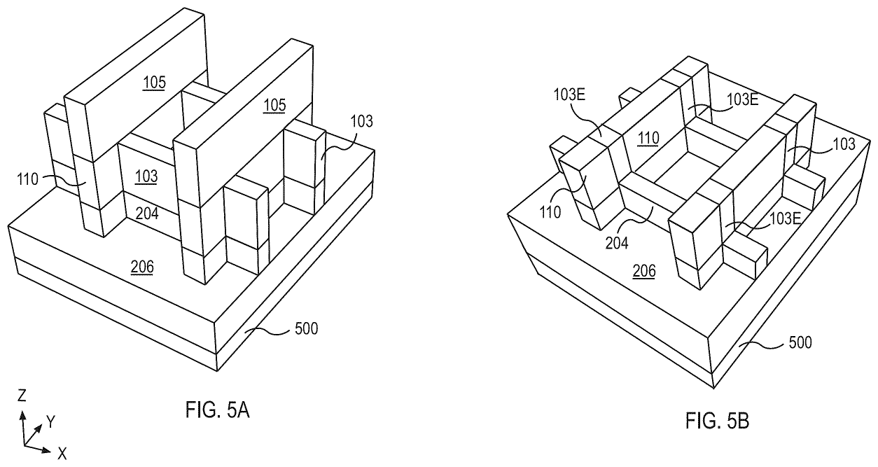

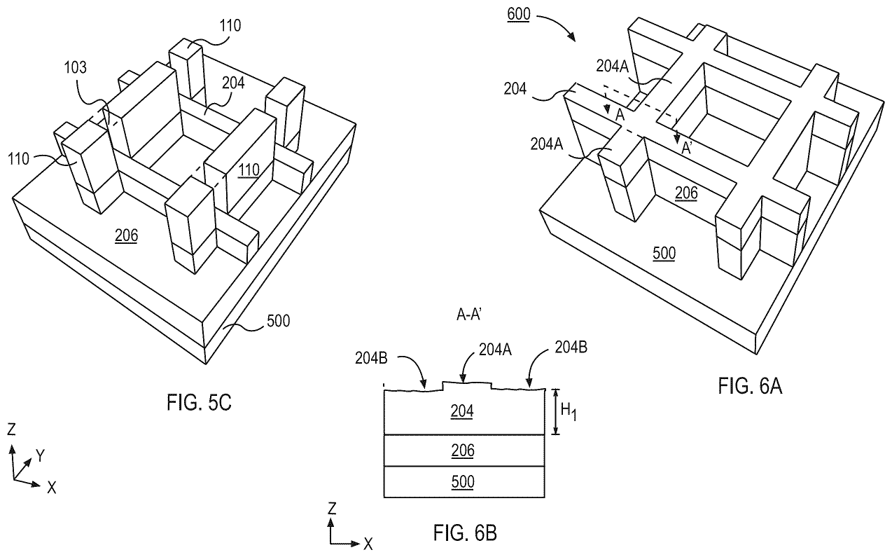

FIG. 5A is an isometric illustration of the structure in FIG. 3B that further includes a stack 500 directly below layer 206, in at least one embodiment. In at least one embodiment, stack 500 includes a substrate and at least one additional layer. In at least one embodiment, stack 500 can include a silicon substrate and a layer of dielectric on the silicon substrate.

FIG. 5B is an isometric illustration of the structure in FIG. 5A following the process to etch lines 105 and 103 selectively to layer 204 and layer 206, in at least one embodiment. In at least one embodiment, process utilized to etch lines 105 and 103 selectively to layer 204 and layer 206 is described in association with FIG. 3C. In at least one embodiment, portions 103E of lines 103 remain adjacent to structure 110 after the etch. In at least one embodiment, portions of lines 103 are masked by lines 105 during the plasma etch to form portions 103E that resemble a pillar structure between structures 110. In at least one embodiment, over-etch is used to remove portions 103E selectively to layer 204. In at least one embodiment, lines 103 and lines 105 are etched at a substantially same rate to expose a top surface of patterned layer 204.

FIG. 5C is an isometric illustration of the structure in FIG. 5B following the process to remove portions 103E from above layer 204 and between structure 110, in at least one embodiment. In at least one embodiment, portions 103E may resemble pillar portions. In at least one embodiment, material of structure 110 may not be removed during the over-etch process. In at least one embodiment, structure 110 remains after removal of portions 103E (within dashed lines). In at least one embodiment, etch process to remove portions 103E may include more polymerizing chemistry than during removal of lines 103 and 105. In at least one embodiment, a polymerizing chemistry is useful to protect layer 204. In at least one embodiment, over etch process may begin with a polymerizing operation to protect layer 204 followed by an etch operation to remove portions 103E.

FIG. 6A is an isometric illustration of the structure in FIG. 5C following the process to etch layer 206 and form mask 600, in accordance with an embodiment of the present disclosure. In at least one embodiment, layer 206 includes a carbon containing material and structure 110 includes a carbon containing material. In at least one embodiment, the process to etch layer 206 also removes structure 110 from above portions of layer 204.

In at least one embodiment, layer 206 includes a carbon containing material and structure 110 includes a material that is different from layer 206. In at least one embodiment, structure 110 is etched selectively to layer 204 and layer 206, prior to etching layer 206.

In at least one embodiment, after the etch process, layer 204 is not only substantially planar but also substantially uniform.

In at least one embodiment, layer 204 which acts as a mask during etching of layer 206 is removed during etching. In at least one embodiment, a patterned layer 206 remains on stack 500.

FIG. 6B is a cross-sectional illustration of the structure in FIG. 6A through the line A-A′, in accordance with at least one embodiment. In at least one embodiment, process of removing lines 103 and 105 and structure 110 forms mask 600 that is substantially planar but includes regions of uneven surfaces. In at least one embodiment, an uppermost surface of layer 204 has surface 204A that is above surface 204B. In at least one embodiment, higher and lower surface portions can result when different top surface portions of layer 204 become exposed at different times during the etch. In at least one embodiment, such variations in height, H₁, of surface 204A and surface 204B as measured from top of layer 206 is less than 50% of H₁.

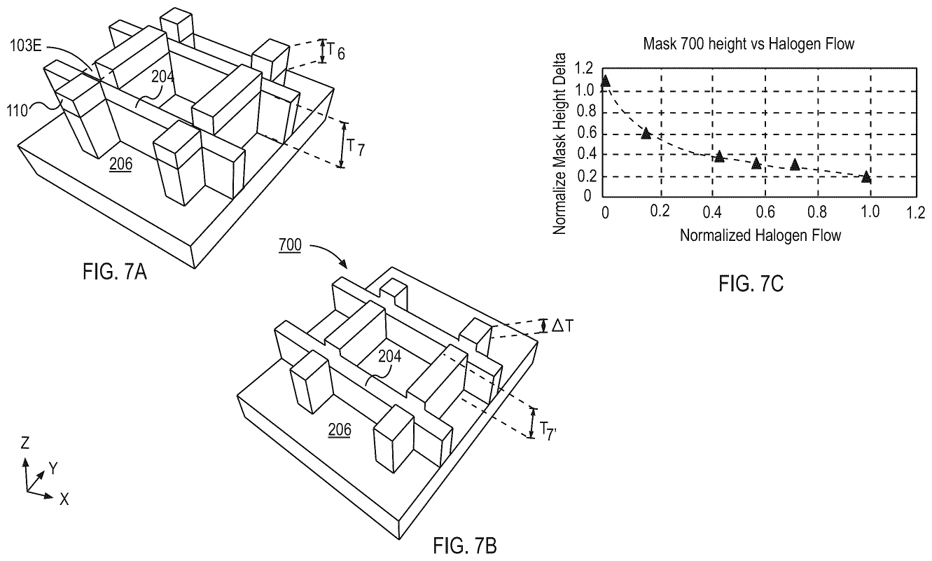

FIG. 7A is a cross-sectional illustration of the structure in FIG. 5B following the process to remove portions 103E, in accordance with an embodiment of the present disclosure. In at least one embodiment, structure 110 includes carbon and layer 204 includes carbon. In at least one embodiment, the material of structure 110 and the material of layer 204 include a substantially same material. In at least one embodiment, the material of structure 110 and the material of layer 204 include a same material, where percentage of carbon may vary by less than 10%, for example.

In at least one embodiment, structure 110 has a thickness T₆. In at least one embodiment, T₆ can be comparable to the incoming thickness of lines 103 (FIG. 3A). In at least one embodiment, T₆ is less than a thickness of structure 110 due to potential erosion during etch of portions 103E. As shown, layer 204 has a thickness T₇. In at least one embodiment, thickness T₇ is greater than thickness T₆ in most applications. In at least one embodiment, difference between thickness T₇ and thickness T₆ is a parameter that defines non planarity of a mask that is to be formed to etch layer 206 below.

In at least one embodiment, layer 206 includes a material different from the material of structure 110 and layer 204. In at least one embodiment, layer 206 may include dielectric materials such as silicon oxide, silicon nitride, or carbon doped silicon oxide or silicon nitride.

FIG. 7B is a cross-sectional illustration of the structure in FIG. 7A following the process to planarize the structure, in accordance with at least one embodiment. In at least one embodiment, an etch process described above may be utilized to selectively planarize layer 204 before etching layer 206. In at least one embodiment, selective planarization can include etching some or all of structure 110.

In at least one embodiment, a plasma etch including halogen chemistry is utilized to remove structure 110. In some such embodiments, portions of layer 204 are also recessed. In at least one embodiment, some of structure 110 remains. In at least one embodiment, all of 110 is removed a mask 700 is formed comprising of layer 204. In at least one embodiment, remaining height of structure 110, thickness T₇ may be equal to or less than thickness T₇ (FIG. 7A). In at least one embodiment, mask 700 includes a step height (delta T), corresponding to the recess in layer 204 and arises from a limited selectivity between etch of structure 110 and layer 204. In at least one embodiment, an increase halogen chemistry can reduce the step height, delta T. In at least one embodiment, increasing halogen can enable polymerizing portions of layer 204 and reducing an effective etch rate of layer 204 as structure 110 is etched.

FIG. 7C is a plot of normalized mask height versus flow of halogens during etching to produce mask FIG. 7B, in accordance with at least one embodiment. In at least one embodiment, step height in mask 700 decreases with increasing halogen gas flow. In at least one embodiment, step height can be reduced by at least 60% by increasing halogen gas flow by approximately 50%. In at least one embodiment, step height can be reduced by approximately 80% by increasing halogen gas flow by approximately 100%.

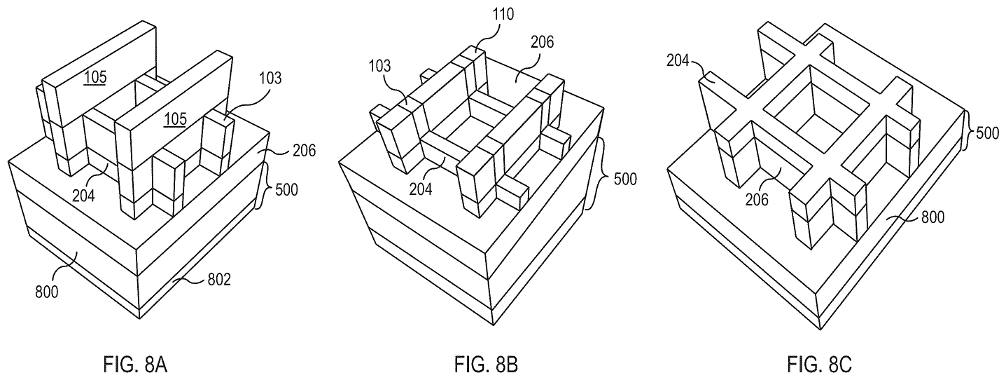

FIG. 8A is an isometric illustration of the structure in FIG. 5A where stack 500 includes dielectric 800 above substrate 802, in accordance with an embodiment of the present disclosure. In at least one embodiment, layer 204 has been patterned.

FIG. 8B is an isometric illustration of the structure in FIG. 8A following the process to etch lines 103 and 105, in accordance with an embodiment of the present disclosure. In at least one embodiment, method of etching lines 103 and 105 have been discussed above in association with FIG. 5B.

FIG. 8C is an isometric illustration of the structure in FIG. 8B following the process to etch layer 206 and form mask 600, in accordance with an embodiment of the present disclosure. In at least one embodiment, process to form mask 600 has been described in association with FIGS. 5C and 6A.

In at least one embodiment, layer 204, that acts as a mask, is removed during etching of the layer 206. In at least one embodiment, patterned layer 206 remains on stack 500.

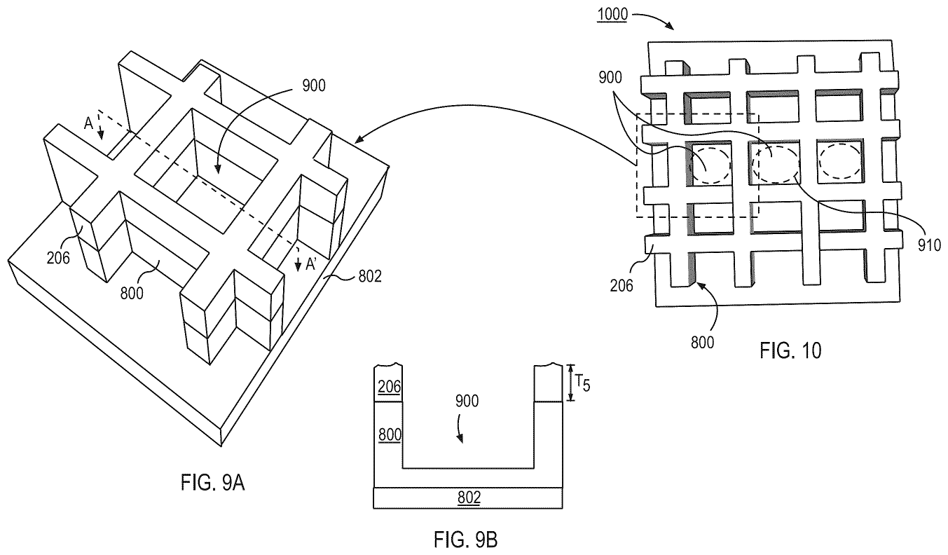

FIG. 9A is an isometric illustration of the structure in FIG. 8C following the process to etch dielectric 800, in accordance with at least one embodiment. In at least one embodiment, dielectric 800 includes a material such as silicon oxide, silicon nitride, silicon oxynitride, carbon doped silicon oxide, or carbon doped silicon nitride or any other low dielectric constant dielectric material that is different from the material of layer 206. In at least one embodiment, plasma etch process forms opening 900 in dielectric 800. In at least one embodiment, layer 204 is completely consumed during etching of dielectric 800. In at least one embodiment, the etch is selectively between the layer 206 and dielectric 800.

FIG. 9B is a cross-sectional illustration of the structure in FIG. 9A though the line A-A′, in accordance with an embodiment of the present disclosure. In at least one embodiment, thickness T₅, of layer 206 can vary between 3-15%.

FIG. 10 is a plan-view illustration of a larger mesh structure 1000 of which the structure in FIG. 9A is a part of, in accordance with at least one embodiment. In at least one embodiment, openings 900 have an area that is substantially the same. In at least one embodiment, the openings 900 may have a width ranging between 3 nm and 60 nm. In at least one embodiment, openings 900 in mask 100 (FIG. 8A) can be rectangular. In at least one embodiment, depending on a maximum width, openings 900 can be substantially circular. In at least one embodiment, openings 900 with a circular pattern can arise when deposition at corners 910 of openings 900 mask the etch process during the progression of patterning described in association with FIGS. 8A-9A.

In at least one embodiment, process of planarizing mask 100 (FIG. 8A) and using mask 100 that is planar to etch dielectric 800 can help to form openings 900 with substantially uniform shape and size.

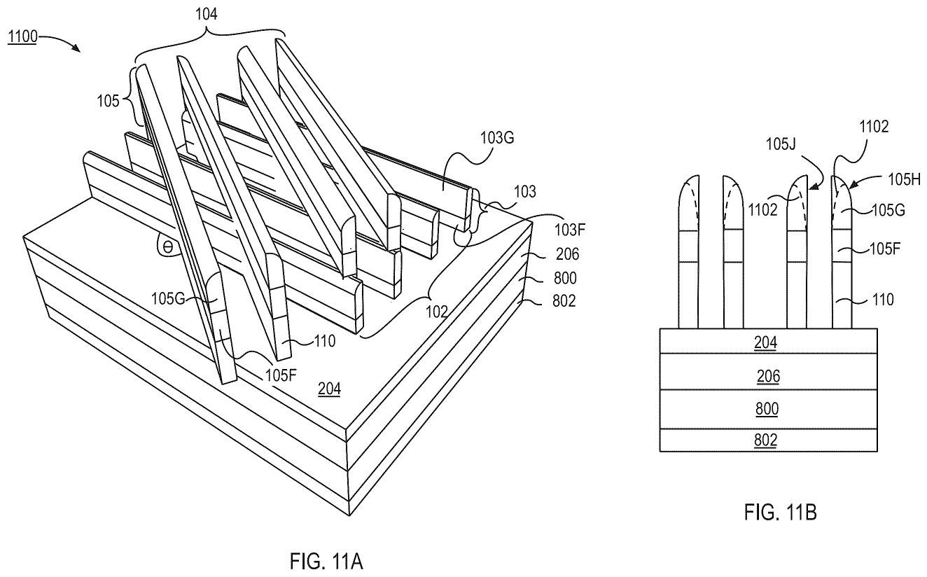

FIG. 11A is an isometric illustration of mask 1100, where patterned structures 102 and 104 include lines 103 and 105, respectively, and where lines 103 and 105 intersect at an angle theta that is not 90 degrees, in accordance with at least one embodiment.

In at least one embodiment, mask 1100 includes one or more elements of mask 100, such as patterned structure 102 and patterned structure 104 and structure 110 between lines 105 and layer 204.

In at least one embodiment, lines 103 and 105 have a plurality of portions. For example, lines 103 include portion 103F and portion 103G on portion 103F. In at least one embodiment, portion 103F includes a different material from the material of portion 103G. In at least one embodiment, lines 103 can have a total height between 10 nm and 60 nm. In at least one embodiment, height or thickness of portion 103F can be similar or different from height or thickness of portion 103G.

In at least one embodiment, lines 105 include portion 105F and portion 105G on portion 105F. In at least one embodiment, portion 105F includes a different material from the material of portion 105G. In embodiments, lines 105 can have a total height between 10 nm and 60 nm. In at least one embodiment, height or thickness of portion 105F can be similar or different from height or thickness of portion 105G.

In at least one embodiment, portions 103F and 105F can include a same material and portions 103G and 105G can include a same material. In at least one embodiment, portions 103G and 105G include silicon nitride, silicon oxynitride, or carbon doped silicon nitride. In at least one embodiment, portions 103F and 105F include silicon oxide, amorphous silicon, or polysilicon. In at least one embodiment, portions 103G and 105G have a thickness between 5 nm and 55 nm.

In at least one embodiment, portions 103G and 105G include silicon oxide, silicon oxynitride or carbon doped silicon oxide. In at least one embodiment, portions 103F and 105F include silicon nitride, carbon doped silicon nitride, or amorphous silicon or polysilicon.

In at least one embodiment, portions 103G and 105G include silicon nitride, silicon oxynitride or carbon doped silicon nitride. In at least one embodiment, portions 103F and 105F include silicon oxide, or carbon doped silicon oxide.

In at least one embodiment, portions 103G and 105G have an asymmetric top component where one sidewall is substantially vertical, and a second sidewall is substantially vertical but has a curved upper surface. In at least one embodiment, the asymmetric top component may be a result of the operations utilized to pattern and form lines 103 and 105.

FIG. 11B a cross-sectional illustration of the structure in FIG. 11A through the line A-A′, in accordance with at least one embodiment. In at least one embodiment, lines 103 are not illustrated for clarity.

In at least one embodiment, lines 105 have sidewall 105H that is curved and sidewall 105J that is substantially vertical. In at least one embodiment, sidewall 105J, that are substantially vertical, can be shaped to include a curved sidewall portion (similar to sidewall 105H that is curved) by a plasma etch process prior to etching layer 204. In at least one embodiment, shaping can enable lines 105 to have a symmetric profile as indicated by dashed lines 1102. In at least one embodiment, an argon bombardment process can be utilized to shape top portion of substantially vertical sidewall 105J to become curve as indicated by dashed lines 1102. In at least one embodiment, a resulting symmetric profile of sidewalls 105H and 105J can enable reduction is non uniformity in size of openings that are formed (such as opening 900 in FIG. 10).

Referring again to FIG. 11A, in at least one embodiment, lines 103 can also have substantially similar symmetric profiles of sidewalls as discussed above. In at least one embodiment, substantially vertical sidewalls of lines 103 can be shaped to have a curve sidewall portion prior to deposition of material of structure 110 and formation of lines 105.

In at least one embodiment, lines 103 and 105 including portions 103F and 103G, and 105F and 105G respectively can also be useful during removal of lines during planarization process described above. In at least one embodiment, portions 103G and 105G can be removed selectively with respect to portions 103F and 105F (FIG. 3C or 5B). In at least one embodiment, a selective removal can enhance uniformity in shape of features within the mask formed by etching layer 204.

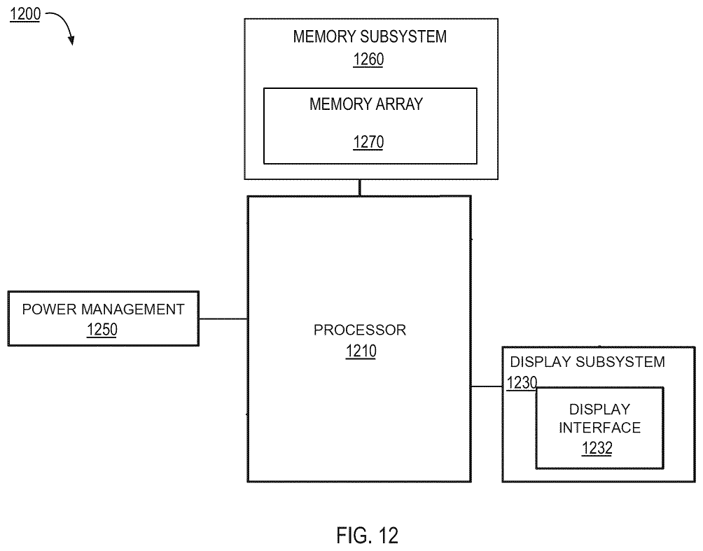

FIG. 12 illustrates a computer system communicatively coupled with a display, in accordance with at least one embodiment. In at least one embodiment, computing device 1200 represents an appropriate computing device, such as a computing tablet, a mobile phone or smart-phone, a laptop, a desktop, an Internet-of-Things (IoT) device, a server, a set-top box, a wireless-enabled e-reader, or the like. It will be understood that certain components are shown generally, and not all components of such a device are shown in computing device 1200.

In at least one embodiment, computing device 1200 includes processor 1210. In at least one embodiment, computing device 1200 comprises a network interface within 1270 such as a wireless interface so that a system embodiment may be incorporated into a wireless device, for example, cell phone or personal digital assistant.

In at least one embodiment, processor 1210 can include one or more physical devices, such as microprocessors, application processors, microcontrollers, programmable logic devices, or other processing means. In at least one embodiment, processing operations performed by processor 1210 include the execution of an operating platform or operating system on which applications and/or device functions are executed. In at least one embodiment, processing operations include operations related to I/O (input/output) with a human user or with other devices, operations related to power management, and/or operations related to connecting the computing device 1200 to another device. The processing operations may also include operations related to audio I/O and/or display I/O.

In at least one embodiment, display subsystem 1230 represents hardware (e.g., display devices) and software (e.g., drivers) components that provide a visual and/or tactile display for a user to interact with the computing device 1200. In at least one embodiment, display subsystem 1230 includes display interface 1232, which includes the particular screen or hardware device used to provide a display to a user. In at least one embodiment, display interface 1232 includes logic separate from processor 1210 to perform at least some processing related to the display. In at least one embodiment, display subsystem 1230 includes a touch screen (or touch pad) device that provides both output and input to a user.

In at least one embodiment, computing device 1200 includes power management 1250 that manages battery power usage, charging of the battery, and features related to power saving operation. In at least one embodiment, memory subsystem 1260 includes memory devices for storing information in computing device 1200. In at least one embodiment, memory can include nonvolatile (state does not change if power to the memory device is interrupted) and/or volatile (state is indeterminate if power to the memory device is interrupted) memory devices. In at least one embodiment, memory subsystem 1260 can store application data, user data, music, photos, documents, or other data, as well as system data (whether long-term or temporary) related to the execution of the applications and functions of computing device 1200. In at least one embodiment, memory subsystem can include a transistor coupled to a storage device such as a capacitor.

In at least one embodiment, transistor and storage device are organized in rows and columns to form a memory array 1270. In at least one embodiment, memory array 1270 can be formed using a mask such as mask 700 described in association with FIG. 7B. In at least one embodiment, mask 700 can be utilized to fabricate openings in dielectric materials. Openings can be further utilized to fabricate trench capacitors.

The term “circuit” or “module” may generally refer to one or more passive and/or active components that are arranged to cooperate with one another to provide a desired function.

The term “signal” may generally refer to at least one current signal, voltage signal, magnetic signal, or data/clock signal. The meaning of “a,” “an,” and “the” include plural references. The meaning of “in” includes “in” and “on.”

The term “scaling” generally refers to converting a design (schematic and layout) from one process technology to another process technology and may be subsequently being reduced in layout area. In some cases, scaling also refers to upsizing a design from one process technology to another process technology and may be subsequently increasing layout area. The term “scaling” generally also refers to downsizing or upsizing layout and devices within the same technology node. The term “scaling” may also refer to adjusting (e.g., slowing down or speeding up—i.e. scaling down, or scaling up respectively) of a signal frequency relative to another parameter, for example, power supply level.

It is pointed out that those elements of the figures having the same reference numbers (or names) as the elements of any other figure can operate or function in any manner similar to that described but are not limited to such.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors (BJT PNP/NPN), BICMOS, CMOS, etc., may be used without departing from the scope of the disclosure.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” “at least one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Following examples are provided that illustrate the various embodiments. The examples can be combined with other examples. As such, various embodiments can be combined with other embodiments without changing the scope of the invention.

Example 1: A method of planarizing, the method comprising: placing a mask formed above a layer into an etch chamber, wherein the mask comprises: a first patterned structure comprising at least a first material; a second patterned structure comprising at least a second material above the first patterned structure, wherein portions of the second patterned structure intersect the first patterned structure to form intersections and at least an opening, wherein the opening exposes the layer; and a structure comprising a third material vertically between portions of the second patterned structure and the layer, wherein the third material is different from the first material or the second material; etching the layer through the opening; etching and removing the first patterned structure and the second patterned structure selectively to the layer; and etching and removing the structure.

Example 2: The method of example 1, wherein the first patterned structure comprises a first pair of lines and the second patterned structure comprises a second pair of lines.

Example 3: The method of example 2, wherein the first pair of lines intersects the second pair of lines at an angle between 30 and 90 degrees.

Example 4: The method of example 2, wherein etching the first pair of lines and the second pair of lines comprises: etching the first pair of lines and the second pair of lines at a substantially same rate to expose a top surface of the layer.

Example 5: The method of example 4, wherein etching the first pair of lines and the second pair of lines further comprises: etching to form pillars of the first pair of lines at the intersections; and further etching and removing the pillars selectively to the layer to produce a substantially planar top surface of the layer.

Example 6: The method of example 1, wherein the layer is a first layer, wherein the first patterned structure comprises a dual layer stack comprising: a second layer on the first layer, the second layer comprising at least silicon; and a first dielectric on the second layer, the first dielectric comprising at least silicon.

Example 7: The method of example 6, wherein the second patterned structure comprises a dual layer stack comprising: a third layer on the first dielectric comprising at least silicon; and a second dielectric on the third layer, the second dielectric comprising at least silicon, and wherein the first dielectric comprises a thickness between 5 nm and 55 nm, and the second dielectric comprises a thickness between 5 nm and 55 nm.

Example 8: The method of example 7, wherein the first patterned structure and the second patterned structure comprise a same material.

Example 9: The method of example 1, wherein etching the second patterned structure comprises a first sidewall that is substantially vertical and a second sidewall opposite to the first sidewall that has a substantially curved upper portion, and wherein prior to etching the layer, the method comprises performing an argon bombardment process to erode the first sidewall to form a curved upper portion.

Example 10: The method of example 1, wherein the layer comprises a fourth material comprising one of carbon, SiO2, SiN, SiCN, poly Si, SiOCH, or low k interlayer dielectric material, wherein the fourth material is different from the third material.

Example 11: The method of example 1, wherein the first material comprises silicon oxide, silicon oxynitride, silicon carbide, silicon nitride, polysilicon or amorphous silicon, wherein the second material comprises silicon oxide, silicon oxynitride, silicon carbide, silicon nitride, polysilicon or amorphous silicon and wherein the third material comprises carbon, SiCN, SION, Si, SiO2, SiN, or SiC.

Example 12: The method of example 1, wherein etching the layer comprises utilizing a plasma etch process, wherein the plasma etch process utilizes halogen containing gas CHx−, Br−, Clx−, or I−.

Example 13: The method of example 1, wherein etching the first patterned structure and the second patterned structure comprises utilizing CF₄, CHxFy, C₄F₈, C₄F₆, Ar, and/or O₂.

Example 14: The method of example 1, wherein the first patterned structure comprises a first plurality of substantially parallel lines and the second patterned structure comprises a second plurality of substantially parallel lines, and wherein the first plurality of substantially parallel lines intersects the second plurality of substantially parallel lines at an angle between 30 and 90 degrees to form a plurality of openings.

Example 15: The method of example 1, wherein the etching and removing the first patterned structure and the second patterned structure form a plurality of openings having a substantially same size.

Example 16: The method of example 15, where the plurality of openings have a width between 3 nm and 60 nm.

Example 17: A method of planarizing, the method comprising: receiving a substrate comprising a mask formed above a patterned layer, wherein the mask comprises: a first patterned structure comprising at least a first material; a second patterned structure comprising at least a second material above the first patterned structure, wherein portions of the second patterned structure intersect the first patterned structure to form intersections and at least an opening; a structure comprising a third material vertically between portions of the second patterned structure and the patterned layer, wherein the third material is different from the first material or the second material; and planarizing the first patterned structure and the second patterned structure.

Example 18: The method of example 17, wherein the first patterned structure comprises a first pair of lines and the second patterned structure comprises a second pair of lines, wherein planarizing the first patterned structure and the second patterned structure comprises etching the first pair of lines and the second pair of lines.

Example 19: The method of example 18, wherein etching the first pair of lines and the second pair of lines comprises etching at a substantially same rate to expose a top surface of the patterned layer.

Example 20: The method of example 18, wherein etching the first pair of lines and the second pair of lines further comprises: etching to form pillars of the first pair of lines at the intersections; and further etching and removing the pillars selectively to the patterned layer to produce a substantially planar top surface of the patterned layer.

Example 21: A method of planarizing, the method comprising: placing a mask formed above a stack of two or more layers into an etch chamber, wherein the mask comprises: a first patterned layer comprising a first material; a second patterned layer comprising a second material above the first patterned layer, wherein portions of the second patterned layer intersect the second patterned layer to form intersections and at least an opening; and a third material vertically between portions of the second patterned layer and the stack of two or more layers, wherein the third material is different from the first material or the second material; etching a first layer of the stack of two or more layers through the opening and exposing a top surface of a second layer below the first layer; and etching and removing the first patterned layer and the second patterned layer selectively to the first layer and the top surface of the second layer.

The method of example 21, wherein the third material includes a carbon containing material and the first layer of the stack of two or more layers includes a carbon containing material.

Example 22: The method of example 21 further comprises etching and removing the third material while etching the second layer of the stack of two or more layers.

Example 23: The method of example 21, wherein the third material includes a carbon containing material and the first layer of the stack of two or more layers includes a carbon containing material.

Example 24: The method of example 21, wherein etching the first layer of the stack of two or more layers comprises utilizing a plasma etch process, wherein the plasma etch process further comprises flowing halogen gas comprising one or more of CHx−, Br−, Clx−, or I− at a flow rate between 0.5 sccm and 500 sccm.

Example 25: A method of planarizing, the method comprising: placing a mask formed above a stack of two or more layers into an etch chamber, wherein the mask comprises: a first patterned layer comprising a first material; a second patterned layer comprising a second material above the first patterned layer, wherein portions of the second patterned layer intersect the second patterned layer to form intersections and at least an opening, wherein the opening further extends into a first layer of the stack and exposes a top surface of a second layer below the first layer; and a third material vertically between portions of the second patterned layer and the stack wherein the third material is different from the first material or the second material; etching and removing the first patterned layer and the second patterned layer selectively to the first layer and the top surface of the second layer; and using the first layer to etch the second layer of the stack.

Example 26: The method of example 25, further comprising: etching and removing the third material while etching the second layer of the stack.

Example 27: A method of planarizing, the method comprising: placing a mask formed above a stack of two or more layers into an etch chamber, wherein the mask comprises: a first patterned layer comprising a first material; a second patterned layer comprising a second material above the first patterned layer, wherein portions of the second patterned layer intersect the second patterned layer to form intersections and at least an opening, wherein the opening further extends into a first layer of the stack and exposes a top surface of a second layer below the first layer; and a third material vertically between portions of the second patterned layer and the stack wherein the third material is different from the first material or the second material; etching and removing the first patterned layer and the second patterned layer selectively to the first layer and the top surface of the second layer; using the first layer to etch the second layer of the stack through the opening; etching and removing the third material; and using the first layer to etch a dielectric layer below the second layer through the opening.

Example 28: The method of example 27, further comprises: etching and removing the third material while etching the second layer of the stack wherein the dielectric comprises SiO₂, SiOC, SiC or SiO₂, SiN.

Example 29: A method of planarizing, the method comprising: placing a mask formed above a layer into an etch chamber, wherein the mask comprises: a first patterned layer comprising a first material; a second patterned layer comprising a second material above the first patterned layer, wherein portions of the second patterned layer intersect the first patterned layer to form intersections and at least an opening, wherein the opening exposes the layer; and a third material on a same level as and adjacent to the first patterned layer, portions of the third material vertically between portions of the second patterned layer and the layer, wherein the third material is different from the first material or the second material; etching the third material through the opening and exposing the layer; etching the layer selectively to the first and second patterned layers and the third material through the opening; etching and removing the first patterned layer and the second patterned layer selectively to the layer; and etching and removing the third material.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the invention should be measured solely by reference to the claims that follow.

1. A method of planarizing, the method comprising:
placing a mask formed above a layer into an etch chamber, wherein the mask comprises:
a first patterned structure comprising at least a first material;
a second patterned structure comprising at least a second material above the first patterned structure, wherein portions of the second patterned structure intersect the first patterned structure to form intersections and at least an opening, and wherein the opening exposes the layer; and
a structure comprising a third material vertically between the portions of the second patterned structure and the layer, wherein the third material is different from the first material or the second material;
etching the layer through the opening;
etching and removing the first patterned structure and the second patterned structure selectively to the layer; and
etching and removing the structure.

2. The method of claim 1, wherein the first patterned structure comprises a first pair of lines and the second patterned structure comprises a second pair of lines.

3. The method of claim 2, wherein the first pair of lines intersects the second pair of lines at an angle between 30 and 90 degrees.

4. The method of claim 2, wherein etching the first pair of lines and the second pair of lines comprises:
etching the first pair of lines and the second pair of lines at a substantially same rate to expose a top surface of the layer.

5. The method of claim 4, wherein etching the first pair of lines and the second pair of lines further comprises:
etching to form pillars of the first pair of lines at the intersections; and
further etching and removing the pillars selectively to the layer to produce a substantially planar top surface of the layer.

6. The method of claim 1, wherein the layer is a first layer, wherein the first patterned structure comprises a first dual layer stack comprising:
a second layer on the first layer, the second layer comprising at least silicon; and
a first dielectric on the second layer, the first dielectric comprising at least silicon.

7. The method of claim 6, wherein the second patterned structure comprises a second dual layer stack comprising:
a third layer on the first dielectric comprising at least silicon; and
a second dielectric on the third layer, the second dielectric comprising at least silicon, and wherein the first dielectric comprises a thickness between 5 nm and 55 nm, and wherein the second dielectric comprises a thickness between 5 nm and 55 nm.

8. The method of claim 7, wherein the first patterned structure and the second patterned structure comprise a same material.

9. The method of claim 1, wherein etching the second patterned structure comprises a first sidewall that is substantially vertical and a second sidewall opposite to the first sidewall that has a substantially curved upper portion, and wherein prior to etching the layer, the method further comprises performing an argon bombardment process to erode the first sidewall to form a curved upper portion.

10. The method of claim 1, wherein the layer comprises a fourth material comprising one of carbon, SiO2, SiN, SiCN, poly Si, SiOCH, or low k interlayer dielectric material, and wherein the fourth material is different from the third material.

11. The method of claim 1, wherein the first material comprises silicon oxide, silicon oxynitride, silicon carbide, silicon nitride, polysilicon or amorphous silicon, wherein the second material comprises silicon oxide, silicon oxynitride, silicon carbide, silicon nitride, polysilicon or amorphous silicon, and wherein the third material comprises carbon, SiCN, SiON, Si, SiO2, SiN, or SiC.

12. The method of claim 1, wherein etching the layer comprises utilizing a plasma etch process, and wherein the plasma etch process utilizes halogen containing gas CHx−, Br−, Clx−, or I−.

13. The method of claim 1, wherein etching the first patterned structure and the second patterned structure comprises utilizing CF₄, CHxFy, C₄F₈, C₄F₆, Ar, and/or O₂.

14. The method of claim 1, wherein the first patterned structure comprises a first plurality of substantially parallel lines and the second patterned structure comprises a second plurality of substantially parallel lines, and wherein the first plurality of substantially parallel lines intersects the second plurality of substantially parallel lines at an angle between 30 and 90 degrees to form a plurality of openings.

15. The method of claim 1, wherein etching and removing the first patterned structure and the second patterned structure form a plurality of openings having a substantially same size.

16. The method of claim 15, wherein the plurality of openings has a width between 3 nm and 60 nm.

17. A method of planarizing, the method comprising:
receiving a substrate comprising a mask formed above a patterned layer, wherein the mask comprises:
a first patterned structure comprising at least a first material;
a second patterned structure comprising at least a second material above the first patterned structure, wherein portions of the second patterned structure intersect the first patterned structure to form intersections and at least an opening;
a structure comprising a third material vertically between portions of the second patterned structure and the patterned layer, wherein the third material is different from the first material or the second material; and
planarizing the first patterned structure and the second patterned structure.

18. The method of claim 17, wherein the first patterned structure comprises a first pair of lines and the second patterned structure comprises a second pair of lines, and wherein planarizing the first patterned structure and the second patterned structure comprises etching the first pair of lines and the second pair of lines.

19. The method of claim 18, wherein etching the first pair of lines and the second pair of lines comprises etching at a substantially same rate to expose a top surface of the patterned layer.

20. The method of claim 18, wherein etching the first pair of lines and the second pair of lines further comprises:
etching to form pillars of the first pair of lines at the intersections; and
further etching and removing the pillars selectively to the patterned layer to produce a substantially planar top surface of the patterned layer.

21. A method of planarizing, the method comprising:
placing a mask formed above a stack of two or more layers into an etch chamber, wherein the mask comprises:
a first patterned layer comprising a first material;
a second patterned layer comprising a second material above the first patterned layer, wherein portions of the second patterned layer intersect the second patterned layer to form intersections and at least an opening; and
a third material vertically between the portions of the second patterned layer and the stack of two or more layers, wherein the third material is different from the first material or the second material;
etching a first layer of the stack of two or more layers through the opening and exposing a top surface of a second layer below the first layer; and
etching and removing the first patterned layer and the second patterned layer selectively to the first layer and the top surface of the second layer.

22. The method of claim 21 further comprises etching and removing the third material while etching the second layer of the stack of two or more layers.

23. The method of claim 21, wherein the third material includes a first carbon containing material and the first layer of the stack of two or more layers includes a second carbon containing material.

24. The method of claim 21, wherein etching the first layer of the stack of two or more layers comprises utilizing a plasma etch process, and wherein the plasma etch process further comprises flowing halogen gas comprising one or more of CHx−, Br−, Clx−, or I− at a flow rate between 0.5 sccm and 500 sccm.
